(19) United States
(12) Patent Application Publication
(10) Pub. No.: US 2011/0044364 A1
(43) Pub. Date: Feb. 24, 2011

(54) STRUCTURE AND METHOD FOR ACHIEVING SELECTIVE ETCHING IN (Ga,Al,In,B)N LASER DIODES

(75) Inventors: Robert M. Farrell, Goleta, CA (US); Daniel A. Haeger, Goleta, CA (US); Po Shan Hsu, Arcadia, CA (US); Umesh K. Mishra, Montecito, CA (US); Steven P. DenBaars, Goleta, CA (US); James S. Speck, Goleta, CA (US); Shuji Nakamura, Santa Barbara, CA (US)

Correspondence Address: GATES & COOPER LLP;HOWARD HUGHES CENTER, 6701 CENTER DRIVE WEST, SUITE 1050, LOS ANGELES, CA, 90045, US

(73) Assignee: THE REGENTS OF THE UNIVERSITY OF CALIFORNIA, Oakland, CA (US)

(21) Appl. No.: 12/859,661

(22) Filed: Aug. 19, 2010

Related U.S. Application Data
(60) Provisional application No. 61/235,284, filed on Aug. 19, 2009.

(51) Int. Cl. H01S 5/028; H01L 21/306

(52) U.S. Cl. 372/45.01; 438/46; 257/E21.215

(57) ABSTRACT

A structure and method that can be used to achieve selective etching in (Ga, Al, In, B) N laser diodes, comprising fabricating (Ga, Al, In, B) N laser diodes with one or more Al-containing etch stop layers.

### CROSS REFERENCE TO RELATED APPLICATIONS

This application claims the benefit under 35 U.S.C. Section 119(e) of co-pending and commonly assigned U.S. Provisional Patent Application Ser. No. 61/235,284, filed on Aug. 19, 2009, by Robert M. Farrell, Daniel A. Haeger, Po Shan Hsu, Umesh K. Mishra, Steven P. DenBaars, James S. Speck, and Shuji Nakamura, entitled “STRUCTURE AND METHOD FOR ACHIEVING SELECTIVE ETCHING IN (Ga, Al, In, B) N LASER DIODES,” attorney's docket number 30794.320-US-P1 (2009-795-1), which application is incorporated by reference herein.

This application is related to co-pending and commonly-assigned U.S. Utility application Ser. No. 12/833,607, filed on Jul. 9, 2010, by Robert M. Farrell, Matthew T. Hardy, Hiroaki Ohta, Steven P. DenBaars, James S. Speck, and Shuji Nakamura, entitled “STRUCTURE FOR IMPROVING THE MIRROR FACET CLEAVING YIELD OF (Ga, Al, In, B) N LASER DIODES GROWN ON NONPOLAR OR SEMIPOLAR (Ga, Al, In, B) N SUBSTRATES,” attorney's docket number 30794.319-US-U1 (2009-762-2), which application claims the benefit under 35 U.S.C. Section 119(e) of co-pending and commonly assigned U.S. Provisional Application Ser. No. 61/224,368 filed on Jul. 9, 2009, by Robert M. Farrell, Matthew T. Hardy, Hiroaki Ohta, Steven P. DenBaars, James S. Speck, and Shuji Nakamura, entitled “STRUCTURE FOR IMPROVING THE MIRROR FACET CLEAVING YIELD OF (Ga, Al, In, B) N LASER DIODES GROWN ON NONPOLAR OR SEMIPOLAR (Ga, Al, In, B) N SUBSTRATES,” attorney's docket number 30794.319-US-P1 (2009-762-1), both of which applications are incorporated by reference herein.

### BACKGROUND OF THE INVENTION

1. Field of the Invention

This invention relates to semiconductor materials, methods, and devices, and more particularly, to the manufacturing of (Ga, Al, In, B) N laser diodes (LDs), wherein a structure and method are described that can be used to achieve selective etching in (Ga, Al, In, B) N LDs, thereby enabling (Ga, Al, In, B) N LDs with improved manufacturability and high performance.

2. Description of the Related Art

(Note: This application references a number of different publications as indicated throughout the specification by one or more reference numbers within brackets, e.g., [Ref x]. A list of these different publications ordered according to these reference numbers can be found below in the section entitled “References.” Each of these publications is incorporated by reference herein.)

The usefulness of GaN and alloys of (Ga, Al, In, B) N has been well established for fabrication of visible and ultraviolet optoelectronic devices and high power electronic devices. Current state-of-the-art (Ga, Al, In, B) N thin films, heterostructures, and devices are grown along the [0001] c-axis. The total polarization of such films consists of spontaneous and piezoelectric polarization contributions, both of which originate from the single polar [0001] c-axis of the wurtzite (Ga, Al, In, B) N crystal structure. When (Ga, Al, In, B) N heterostructures are grown pseudomorphically, polarization discontinuities are formed at surfaces and interfaces within the crystal. These discontinuities lead to the accumulation or depletion of carriers at surfaces and interfaces, which in turn produce electric fields. Since the alignment of these polarization-induced electric fields coincides with the typical [0001] growth direction of (Ga, Al, In, B) N thin films and heterostructures, these fields have the effect of “tilting” the energy bands of (Ga, Al, In, B) N devices.

In c-plane (Ga, Al, In, B) N quantum wells, the “tilted” energy bands spatially separate the electron and hole wavefunctions. This spatial charge separation reduces the oscillator strength of radiative transitions and red-shifts the emission wavelength. These effects are manifestations of the quantum confined Stark effect (QCSE) and have been thoroughly analyzed for (Ga, Al, In, B) N quantum wells (QWs) [Refs. 1, 2]. Additionally, the large polarization-induced electric fields can be partially screened by dopants and injected carriers [Ref 3], making the emission characteristics difficult to engineer accurately.

Commercially-available c-plane LDs typically employ thin (≦4 nm) InGaN QWs due to the presence of polarization-related electric fields. Thus, thick Al-containing waveguide cladding layers, such as AlGaN/GaN superlattices or bulk AlGaN, are needed to provide sufficient optical mode confinement in c-plane (Ga, Al, In, B) N LDs.

One approach to decreasing polarization effects in (Ga, Al, In, B) N devices is to grow the devices on nonpolar planes of the crystal [Ref 4]. These include the {11-20} planes, known collectively as a-planes, and the {10-10} planes, known collectively as m-planes. Such planes contain equal numbers of gallium and nitrogen atoms per plane and are charge-neutral. Subsequent nonpolar layers are equivalent to one another, so the bulk crystal will not be polarized along the growth direction.

Unlike conventional (Ga, Al, In, B) N LDs grown on c-plane GaN substrates, the absence of polarization-related electric fields in m-plane light-emitting devices allow for the implementation of relatively thick (8 nm) InGaN QWs in m-plane (Ga, Al, In, B) N LEDs and LDs without a reduction in radiative efficiency [Ref 6]. These thick InGaN QWs provide adequate transverse waveguiding of the optical mode without the need for Al-containing waveguide cladding layers, enabling the demonstration of ACF (Ga, Al, In, B) N LDs [Refs. 7, 8]. Similar designs, involving the use of an InGaN-based separate confinement heterostructure with GaN cladding layers, also alleviate the need for Al-containing waveguide cladding layers [Ref. 9].

Another approach to reducing polarization effects in (Ga, Al, In, B) N devices is to grow the devices on semipolar planes of the crystal [Ref. 5]. The term “semipolar plane” can be used to refer to any plane that cannot be classified as c-plane, a-plane, or m-plane. In crystallographic terms, a semipolar plane would be any plane that has at least two nonzero h, i, or k Miller indices and a nonzero l Miller index. Subsequent semipolar layers are equivalent to one another, so the bulk crystal will have reduced polarization along the growth direction.

Current conventional commercially-available (Ga, Al, In, B) N LD structures are grown on the c-plane of the wurtzite (Ga, Al, In, B) N crystal structure. Due to the lack of a robust selective etching process, manufacturers typically use timing and/or laser interferometry techniques to control ridge waveguide etch depths in ridge waveguide geometry devices. Such techniques often have issues with reproducibility and accuracy, causing manufacturing problems and reducing overall device yields.

In contrast, the manufacturers of III-arsenide-based and III-phosphide-based LDs typically use selective etching techniques to control the consistency and accuracy of their etching processes [Refs. 10, 11]. Similar techniques have been reported for (Ga, Al, In, B) N heterostructures [Refs. 12, 13], but have yet to be demonstrated in (Ga, Al, In, B) N LDs.

Studies by Buttari et al. demonstrated that plasmas containing a mixture of BCl₃ and SF₆ could be used to achieve selective etching between GaN and AlGaN layers [Ref 14]. Pure BCl₃ was found to be virtually ineffective in etching GaN, most likely due to the low concentration of active chlorine atoms in pure BCl₃ plasmas [Ref 15]. The intermixing of SF₆ and BCl₃ was found to increase the population of chlorine radicals (etching agents) and of fluorine radicals (inhibitor agents), increasing the etch rate of GaN and decreasing the etch rate of AlGaN [Refs. 14, 15]. The decrease in the AlGaN etch rate was found to be due to the formation of nonvolatile AIF₃ residues on the AlGaN surface, analogous to previous studies on GaAs and AlGaAs [Ref 16]. The non-volatility of AIF₃ was found to reduce the etching efficiency of chlorine radicals, allowing for the selective etching of GaN over AlGaN [Ref. 14].

The advent of ACF (Ga, Al, In, B) N LDs has made the growth of LD structures with Al-containing etch stop layers (ESLs) surrounded by binary GaN layers possible, enabling highly selective etching between the ESLs and the surrounding layers. Based on this concept, the present invention describes a structure and method that can be used to achieve selective etching in (Ga, Al, In, B) N LDs.

The implementation of ESLs in (Ga, Al, In, B) N LDs should lead to significant improvements in the consistency and accuracy of etching processes. These improvements should result in a number of advantages for (Ga, Al, In, B) N LD manufacturers, including, but not limited to, higher overall device yield, lower threshold current densities, greater modal stability, higher kink-free output power levels, and longer device lifetimes.

### SUMMARY OF THE INVENTION

To overcome the limitations in the prior art described above, and to overcome other limitations that will become apparent upon reading and understanding the present specification, the present invention discloses a structure and method that can be used to achieve selective etching in (Ga, Al, In, B) N LDs. Specifically, the present invention discloses a method of fabricating a (Ga, Al, In, B) N laser diode with one or more Al-containing etch stop layers, as well as the resulting optoelectronic device. The etch stop layers are layers that are used to control an etch depth of one or more etched layers in the device, wherein the etched layers comprise selectively etched layers between the etch stop layers and other layers in the device. The etch stop layers are bordered by layers comprised of n-type doped, p-typed doped, or undoped alloys of (Ga, Al, In, B) N. Finally, the etch stop layers may or may not also function as electron blocking layers.

### BRIEF DESCRIPTION OF THE DRAWINGS

Referring now to the drawings in which like reference numbers represent corresponding parts throughout:

FIG. 1 is a flowchart that illustrates a method that can be used to achieve selective etching in (Ga, Al, In, B) N LDs according to a preferred embodiment of the present invention.

FIG. 2A is a schematic of the epitaxial structure and device geometry of a sample A.

FIG. 2B is a schematic of the epitaxial structure and device geometry of a sample B.

FIG. 3 shows the calculated one-dimensional (1-D) transverse mode profile of sample A.

FIG. 4 plots the measured etch depth as a function of etch time for sample A.

FIG. 5 shows surface profiles of sample A and sample B following a 30 minute dry etch and the deposition of a 250 nm Ta₂O₅ insulator layer.

FIG. 6 plots the light-current-voltage (L-I-V) characteristic for a 4.5 μm wide by 500 μm long LD fabricated from sample A.

FIG. 7 plots the emission spectra above threshold for a 4.5 μm wide by 500 μm long LD fabricated from sample A.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Technical Description

Sample Structure and Growth

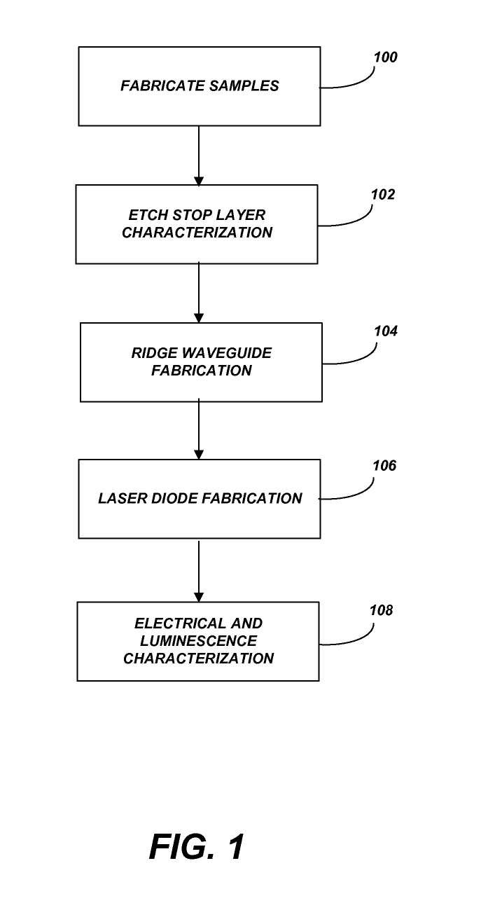

FIG. 1 is a flowchart that illustrates a method that can be used to achieve selective etching in (Ga, Al, In, B) N LDs according to a preferred embodiment of the present invention.

Block 100 of FIG. 1 represents two different samples being fabricated to evaluate the effects of an AlGaN ESL on the ridge waveguide etching process.

The present invention has experimentally demonstrated these effects in ACF (Ga, Al, In, B) N LDs grown by metal organic chemical vapor deposition (MOCVD) on free-standing m-plane GaN substrates manufactured by Mitsubishi Chemical Co., Ltd. These substrates were grown by hydride vapor phase epitaxy (HVPE) in the c-direction and then sliced to expose the m-plane surface. The m-plane surface was prepared by chemical and mechanical surface treatment techniques. The substrates had threading dislocation densities of less than 5×10⁶ cm⁻², carrier concentrations of approximately 1×10¹⁷ cm⁻³, and an RMS surface roughness of less than 1 nm, as measured by the manufacturer.

The MOCVD growth conditions used for the m-plane films were very similar to the growth conditions typically used for c-plane films. All MOCVD growth was performed at atmospheric pressure (AP), at typical V/III ratios (>3000), and at typical growth temperatures (>1000° C.). Trimethylgallium (TMGa) or triethylgallium (TEGa), trimethylindium (TMIn), trimethylaluminum (TMAl), ammonia (NH₃), Bis(cyclopentadienyl)magnesium (Cp₂Mg), and silane (SiH₄) were used as the Ga, In, Al, N, Mg, and Si precursors, respectively.

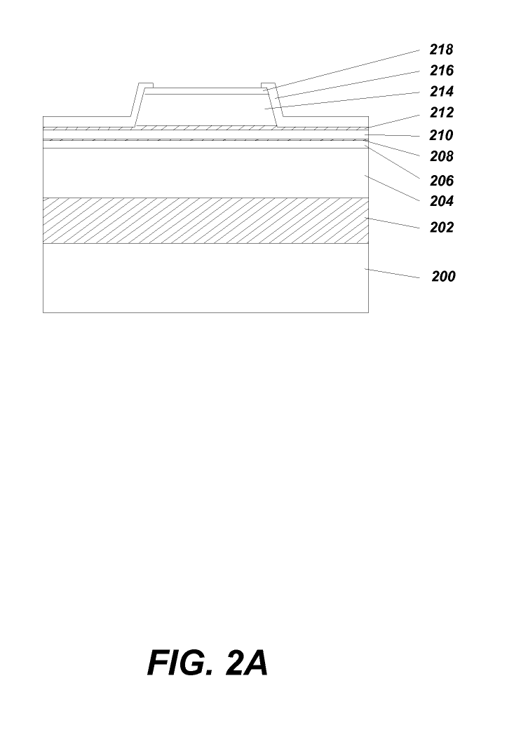

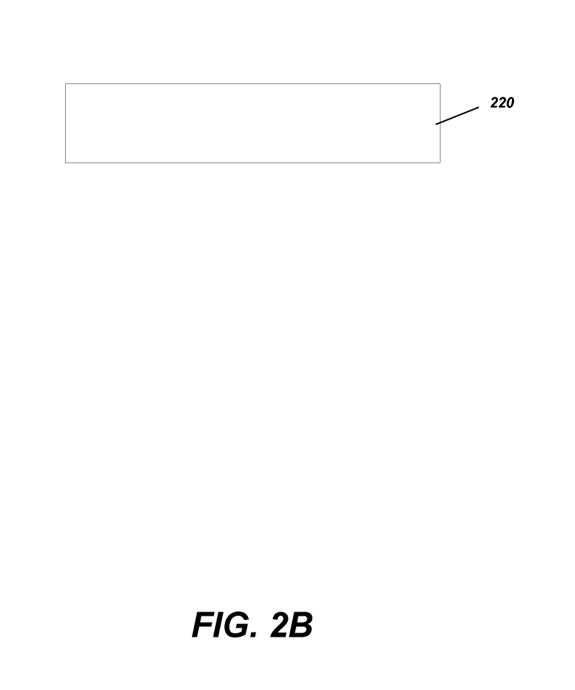

FIG. 2A is a schematic of the epitaxial structure and device geometry of a first sample, known as sample A, which did not contain any Al-containing waveguide cladding layers. Sample A was similar to ACF LD structures reported elsewhere [Refs. 7, 8]. The ACF LD structure of FIG. 2A comprises a 10 μm Si-doped n-GaN template layer 200, a 1 μm Si-doped n-Al_{0.06}Ga_{0.94}N cleave assistance layer (CAL) 202 [Ref. 17], a 1 μm Si-doped n-GaN cladding layer 204, a 5 period undoped In_{0.10}Ga_{0.90}N/GaN multiple-quantum-well (MQW) structure 206 with 8 nm In_{0.10}Ga_{0.90}N quantum wells (QWs) and 8 nm GaN barriers, a 15 nm Mg-doped p-Al_{0.12}Ga_{0.88}N electron blocking layer (EBL) 210, a 200 nm Mg-doped lower p-GaN cladding layer 212, a 40 nm Mg-doped p-Al_{0.09}Ga_{0.91}N ESL 214, an 800 nm Mg-doped upper p-GaN cladding layer 216, and a 20 nm highly Mg-doped p⁺⁺-GaN contact layer 218.

FIG. 2B is a schematic of the epitaxial structure and device geometry of a second sample, known as sample B, which simply comprises a single 10 μm Si-doped n-GaN template layer 220.

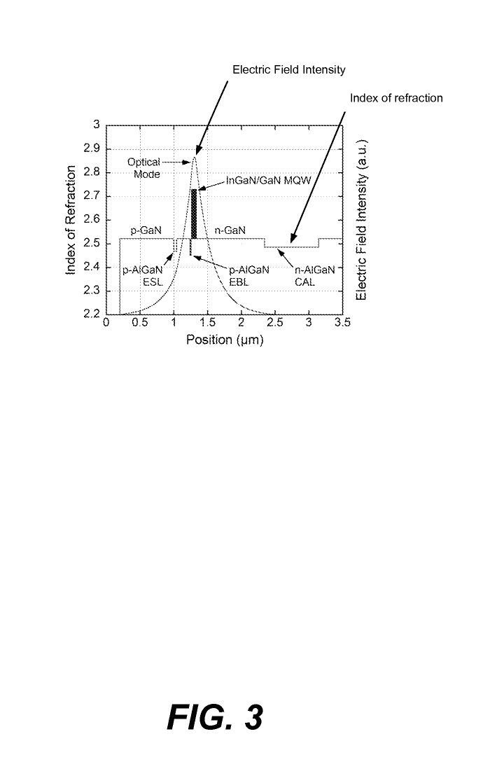

Unlike conventional (Ga, Al, In, B) N LDs grown on c-plane GaN substrates, the ACF LD structure of sample A described in FIG. 2A contained relatively thick 8 nm In_{0.10}Ga_{0.90}N QWs. The calculated one-dimensional (1-D) transverse mode profile for sample A is presented in FIG. 3. The model used index of refraction values at 405 nm of 2.522, 2.487, 2.730, 2.469, and 2.451 for the GaN, Al_{0.06}Ga_{0.94}N, In_{0.10}Ga_{0.90}N, Al_{0.09}Ga_{0.88}N, and Al_{0.12}Ga_{0.88}N layers, respectively [Ref 18]. As illustrated by the calculated mode profile, the 1 μm Si-doped n-Al_{0.06}Ga_{0.94}N CAL and 40 nm Mg-doped p-Al_{0.09}Ga_{0.91}N ESL had little effect on the optical mode, which was guided primarily by the In_{0.10}Ga_{0.90}N/GaN MQW. The calculated transverse confinement factor, Γ, for this structure was 0.147. Hence, even though sample A contained a 1 μm Si-doped n-Al_{0.06}Ga_{0.94}N CAL, a 15 nm Mg-doped p-Al_{0.12}Ga_{0.88}N EBL, and a 40 nm Mg-doped p-Al_{0.09}Ga_{0.91}N ESL, sample A is still referred to as an ACF LD structure.

Etch Stop Layer Characterization

Following the MOCVD growth, a portion of sample A was used to characterize the effectiveness of the p-Al_{0.09}Ga_{0.91}N ESL in controlling the etch depth. This is represented by Block 102 of FIG. 1.

Photoresist was used to pattern features on the samples, which served as an etch mask during the dry etching process. All dry etching was done in a Panasonic E620 inductively coupled plasma (ICP) etching system.

Prior to the actual dry etch, all samples were pretreated with a BCl₃ deoxidizing plasma for 5 minutes to remove native surface oxides [Ref. 19]. Pure BCl₃ was found to be virtually ineffective in etching GaN, most likely due to the low concentration of active chlorine atoms in pure BCl₃ plasmas [Ref. 15]. For the pretreatment step, the chamber pressure was set to 37.5 mTorr, the BCl₃ flow rate was set to 25 sccm, the ICP power was set to 200 W, and the RF power was set to 30 W.

After the pretreatment step, the samples were etched in a plasma containing a mixture of BCl₃ and SF₆. For this step, the chamber pressure was set to 37.5 mTorr, the BCl₃ flow rate was set to 20 sccm, the SF₆ flow rate was set to 5 sccm, the ICP power was set to 200 W, and the RF power was set to 60 W. Details regarding the optimization of the etch conditions and the physical mechanisms behind the selective etching are described elsewhere [Ref 14].

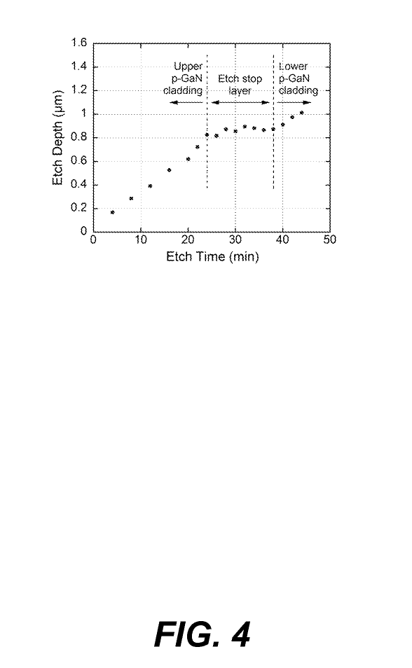

After completing of the etching process, the remaining photoresist mask was stripped from the samples and the height of the features was measured using a Dektak VI profilometer. The measured etch depth as a function of etch time is illustrated in FIG. 4. For etch times between 0 and 24 minutes, the etch depth increased linearly with time with an etch rate of 31.6 nm/min as the etch proceeded through the upper p-GaN cladding layer. However, for etch times between 24 and 38 minutes, the etch depth changed very slowly with time, remaining at around a depth of 800 to 900 nm for a total of 14 minutes. This depth corresponded well with the expected depth of the p-Al_{0.09}Ga_{0.91}N ESL, as determined by MOCVD growth rate calibrations. Finally, for etch times greater than 38 minutes, the etch depth once again increased linearly with time, signifying that the etch had proceeded through the p-Al_{0.09}Ga_{0.91}N ESL and entered the lower p-GaN cladding layer. Based on a calibrated thickness of 40 nm for the p-Al_{0.09}Ga_{0.91}N ESL and a total etch time of 14 minutes, the calculated etch rate for the p-Al_{0.09}Ga_{0.91}N ESL was 2.9 nm/min. This gives a p-GaN/p-Al_{0.09}Ga_{0.91}N etch selectivity of 10.9, verifying the effectiveness of the ESL for controlling the etch depth.

Ridge Waveguide Fabrication

Following characterization of the BCl₃/SF₆ etch, samples A and B were processed into a ridge waveguide geometry structures using a self-aligned ridge waveguide process. This is represented by Block 104 of FIG. 1.

First, ridge waveguides oriented along the [0001] c direction were defined by photolithography using a two-layer photoresist technique. The lithography conditions were adjusted such that the lower resist layer had a slight undercut compared to the upper resist layer to facilitate later lift-off processes.

Next, samples A and B were etched for 30 minutes using the BCl₃/SF₆ etch conditions described above with the two-layer photoresist acting as the etch mask.

After the dry etch, 250 nm of Ta₂O₅ was deposited on the samples by ion beam deposition (IBD) for electrical isolation of the ridges.

Next, the Ta₂O₅ remaining on the top of the ridges was removed by lifting off the remainder of the photoresist mask in a photoresist stripper. FIG. 2A illustrates the geometry of sample A immediately following the Ta₂O₅ insulator lift-off.

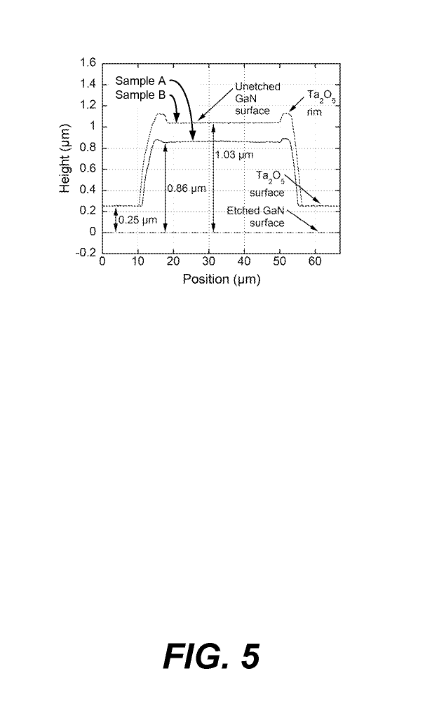

After the completion of the Ta₂O₅ lift-off, a Dektak VI profilometer was used to measure the surface profiles of samples A and B to compare the etch depths on the two samples. As shown in FIG. 5, the etch depth between samples A and B differed considerably. Taking into account the 250 nm Ta₂O₅ layer, the total etch depth for sample A was only 0.86 μm, while the total etch depth for sample B was 1.03 μm, indicating the etch stopping effect of the p-Al_{0.09}Ga_{0.91}N ESL in sample A.

Laser Diode Fabrication

After lifting off the Ta₂O₅ insulator, sample A was processed into a completed ridge waveguide geometry LD structure. This is represented by Block 106 of FIG. 1.

Thick Pd/Au contacts were deposited on top the ridge waveguides to form the p-contacts.

Following the p-contact deposition, the sample was thinned by mechanical grinding and lapping to a thickness of about 50 μm.

Next, a diamond-stylus-based wafer scribing tool was used in conjunction with a periodic skip-scribe technique to prepare the sample for facet cleaving. The skip-scribe technique consisted of scribing the epitaxial side of the sample with a collinear set of periodic 85 μm skip steps and 115 μm scribe steps across the wafer. The scribe direction was aligned with the a-axis of the crystal to facilitate cleaving along the {0001} planes of the crystal. During the skip steps, the diamond stylus was lifted up from the surface of the wafer, leaving the wafer unscribed for a distance of 85 μm. This 85 μm skip length coincided with the location of the individual ridge waveguides.

After the scribing process was completed, sample A was cleaved into laser bars with a cavity length of 500 μm.

Finally, a common n-contact was made to the n-type GaN substrate of each laser bar to enable the electrical and luminescence characterization of the unpackaged and uncoated LDs.

Electrical and Luminescence Characterization of the Laser Diodes

Block 108 of FIG. 1 represents electrical and luminescence characterization of the laser diodes being performed.

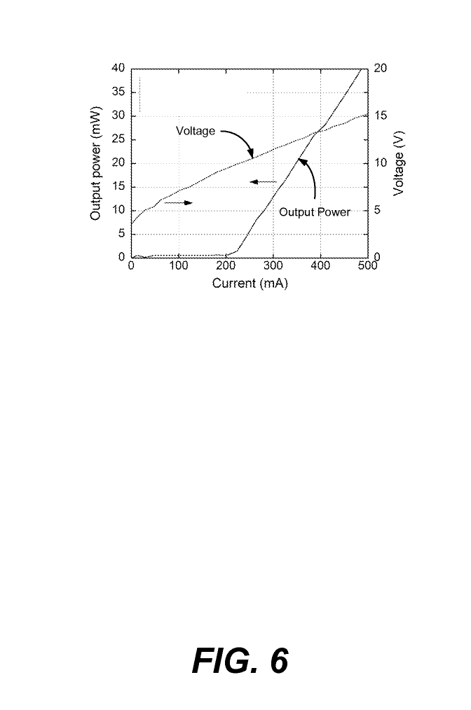

FIG. 6 shows a typical pulsed light-current-voltage (L-I-V) characteristic for a 4.5 μm wide by 500 μm long LD fabricated from sample A. The optical output power was measured from a single uncoated mirror facet with a calibrated Si photodetector at a stage temperature of 20° C. with a pulse width of 1 μs and a repetition rate of 1 kHz, corresponding to a duty cycle of 0.1%. The threshold voltage and series resistance were 9.7 V and 20Ω, respectively. The measured threshold current was 209.5 mA, corresponding to a threshold current density of 9.3 kA/cm².

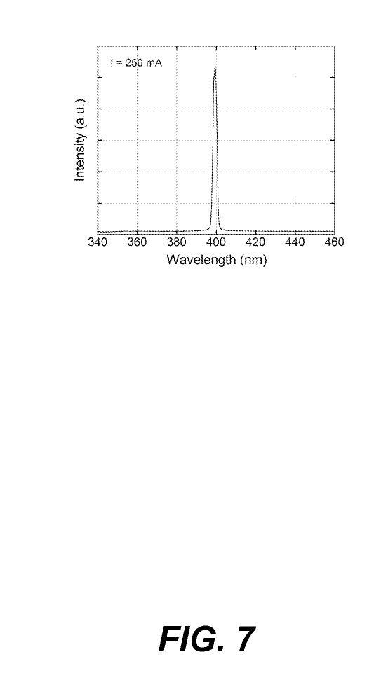

The emission spectrum for the same LD is presented in FIG. 7. The spectrum was collected above threshold at a drive current of 250 mA, indicating a peak lasing wavelength of 399.5 nm.

The above description describes a structure and method that can be used to achieve selective etching in (Ga, Al, In, B) N LDs. While the above description describes ACF (Ga, Al, In, B) N LDs grown on free-standing nonpolar substrates, the scope of this invention also includes (Ga, Al, In, B) N LDs with one or more Al-containing waveguide cladding layers and (Ga, Al, In, B) N LDs grown all possible crystallographic orientations of all possible foreign substrates.

Improvements in consistency and accuracy of the etching process can also be achieved by structural or methodological modifications to these current laser designs and etching techniques.

Possible Variations and Modifications

Variations in MOCVD growth conditions such as growth temperature, growth pressure, VIII ratio, precursor flows, and source materials are also possible without departing from the scope of the present invention. Control of interface quality is an important aspect of the process and is directly related to the flow switching capabilities of particular reactor designs. Continued optimization of the growth conditions should result in more accurate compositional and thickness control of the (Ga, Al, In, B) N thin films described above.

The (Ga, Al, In, B) N LDs described above were comprised of multiple homogenous layers. However, the scope of this invention also includes (Ga, Al, In, B) N LDs comprised of multiple layers having varying or graded compositions.

Additional impurities or dopants can also be incorporated into the (Ga, Al, In, B) N thin films described in this invention. For example, Fe, Mg, Si, and Zn are frequently added to various layers in (Ga, Al, In, B) N heterostructures to alter the conduction properties of those and adjacent layers. The use of such dopants and others not listed here are within the scope of the invention.

The scope of this invention also covers more than just the one nonpolar orientation (m-plane) cited in the technical description. This idea is also pertinent to all polar, nonpolar, and semipolar planes that can be used for growing (Ga, Al, In, B) N-based semiconductor devices. The term “nonpolar plane” includes the {11-20} planes, known collectively as a-planes, and the {10-10} planes, known collectively as m-planes. The term “semipolar plane” can be used to refer to any plane that cannot be classified as c-plane, a-plane, or m-plane. In crystallographic terms, a semipolar plane would be any plane that has at least two nonzero h, i, or k Miller indices and a nonzero l Miller index.

This invention also covers the selection of particular crystal polarities. The use of curly brackets, {}, throughout this document denotes a family of symmetry-equivalent planes. Thus, the {10-12} family includes the (10-12), (-1012), (1-102), (-1102), (01-12), and (0-112) planes. All of these planes are Ga-polarity, meaning that the crystal's c-axis points away from the substrate. Likewise, the {10-1-2} family includes the (10-1-2), (-101-2), (1-10-2), (-110-2), (01-1-2), and (0-11-2) planes. All of these planes are N-polarity, meaning that the crystal's c-axis will point towards the substrate. All planes within a single crystallographic family are equivalent for the purposes of this invention, though the choice of polarity can affect the behavior of the growth process. In some applications it would be desirable to grow on N-polarity planes, while in other cases growth on Ga-polarity planes would be preferred. Both polarities are acceptable for the practice of this invention.

Moreover, substrates other than free-standing nonpolar (Ga, Al, In, B) N substrates could be used for (Ga, Al, In, B) N LD growth. The scope of this invention includes the growth of (Ga, Al, In, B) N LDs on all possible crystallographic orientations of all possible foreign substrates. These foreign substrates include, but are not limited to, silicon carbide, gallium nitride, silicon, zinc oxide, boron nitride, lithium aluminate, lithium niobate, germanium, aluminum nitride, lithium gallate, partially substituted spinels, and quaternary tetragonal oxides sharing the γ-LiAlO₂ structure.

Furthermore, variations in (Ga, Al, In, B) N nucleation (or buffer) layers and nucleation layer growth methods are acceptable for the practice of this invention. The growth temperature, growth pressure, orientation, and composition of the nucleation layers need not match the growth temperature, growth pressure, orientation, and composition of the subsequent thin films and heterostructures. The scope of this invention includes the growth of (Ga, Al, In, B) N LDs on all possible substrates using all possible nucleation layers and nucleation layer growth methods.

The nonpolar (Ga, Al, In, B) N LDs described above were grown on free-standing nonpolar GaN substrates. However, the scope of this invention also covers (Ga, Al, In, B) N LDs grown on epitaxial laterally overgrown (ELO) (Ga, Al, In, B) N templates. The ELO technique is a method of reducing the density of threading dislocations (TD) in subsequent epitaxial layers. Reducing the TD density can lead to improvements in device performance. For c-plane (Ga, Al, In, B) N LDs, these improvements can include increased internal quantum efficiencies, reduced threshold current densities, and longer device lifetimes [Ref 20]. These advantages will be pertinent to all (Ga, Al, In, B) N LDs grown on ELO templates on all possible crystallographic orientations.

The technical description presented above discussed the growth of nonpolar (Ga, Al, In, B) N LDs on free-standing nonpolar GaN substrates that were grown by HVPE in the c-direction and then sliced to expose the m-plane surface. Free-standing polar, nonpolar, or semipolar (Ga, Al, In, B) N substrates may also be created by removing a foreign substrate from a thick polar, nonpolar, or semipolar (Ga, Al, In, B) N layer, by sawing a bulk (Ga, Al, In, B) N ingot or boule into individual polar, nonpolar, or semipolar (Ga, Al, In, B) N wafers, or by any other possible crystal growth or wafer manufacturing technique. The scope of this invention includes the growth of polar, nonpolar, or semipolar (Ga, Al, In, B) N LDs on all possible free-standing polar, nonpolar, or semipolar (Ga, Al, In, B) N wafers created by all possible crystal growth methods and wafer manufacturing techniques.

The technical description presented above discussed using a plasma containing BCl₃ and SF₆ to achieve selective dry etching in the (Ga, Al, In, B) N LDs. However, the plasma could have contained process gases other than BCl₃ and SF₆ to achieve selective dry etching in the (Ga, Al, In, B) N LDs. The scope of this invention includes the use of all possible process gases to achieve selective dry etching in (Ga, Al, In, B) N LDs.

The technical description presented above discussed using a plasma to achieve selective dry etching in the (Ga, Al, In, B) N LDs. However, the etching process could have used one or more solution-based etchants to achieve selective wet etching in the (Ga, Al, In, B) N LDs. The scope of this invention includes the use of all possible solution-based etchants to achieve selective wet etching in (Ga, Al, In, B) N LDs.

The technical description presented above discussed using a 40 nm Mg-doped p-Al_{0.09}Ga_{0.91}N layer as the ESL. However, an Al-containing layer of any composition or thickness could have been used for the ESL. The use of all ESLs with all possible compositions and thicknesses is suitable for the practice of this invention.

The technical description presented above discussed using an Al-containing ESL in an ACF (Ga, Al, In, B) N LD, wherein the ESL was bordered by layers composed of n-type doped, p-typed doped, or undoped GaN. However, the ESL could have also been bordered by layers composed of any n-type doped, p-typed doped, or undoped alloy of (Ga, Al, In, B) N. In addition, the ESL could have been used in a (Ga, Al, In, B) N LD with Al-containing waveguide cladding layers. Such a structure would probably reduce the etch selectivity between the ESL and the surrounding layers, but its use is still within the scope of this invention. The scope of this invention includes the use of all possible ESLs in all possible (Ga, Al, In, B) N LD structures, including situations where the ESLs are bordered by layers composed of any n-type doped, p-typed doped, or undoped alloy of (Ga, Al, In, B) N.

The technical description presented above discussed growing ACF (Ga, Al, In, B) N LDs with a 5 period undoped InGaN/GaN MQW active region with 8 nm InGaN QWs and 8 nm GaN barriers. These layers provided sufficient optical confinement for the device's operation in the absence of Al-containing cladding layers. However, the devices may also contain one or more waveguiding layers with a refractive index greater than that of GaN. In this alternative structure, the QW active region and the waveguiding layers would function together as the waveguide core. The use of any waveguiding layers with a refractive index greater than that of GaN is suitable for the practice of this invention.

Moreover, the present invention is not limited to the use of InGaN/GaN active regions in (Ga, Al, In, B) N LDs. Other alloys of (Ga, Al, In, B) N may be used in the active regions in (Ga, Al, In, B) N LDs for the practice of this invention. Likewise, the present invention is not limited to a particular thickness for the active region or for the QWs, although QW thicknesses are typically greater than 4 nm for nonpolar and semipolar QWs. The use of an active region with layers of any composition or thickness is suitable for the practice of this invention.

The technical description presented above discussed using two distinct Al-containing layers for the ESL and the EBL in the (Ga, Al, In, B) N LDs. However, one or more ESLs could function as an EBL for the practice of this invention. Likewise, one or more EBLs could function as an ESL for the practice of this invention. The scope of this invention covers all possible ESLs in all possible (Ga, Al, In, B) N LD structures, regardless of whether the ESLs also function as EBLs.

Nomenclature

The term “(Ga, Al, In, B) N” or III-nitride as used herein is intended to be broadly construed to include respective nitrides of the single species, Al, Ga, In and B, as well as binary, ternary and quaternary compositions of such Group III metal species. Accordingly, the term (Ga, Al, In, B) N comprehends the compounds AlN, GaN, and InN, as well as the ternary compounds AlGaN, GaInN, and AlInN, and the quaternary compound AlGaInN, as species included in such nomenclature. When two or more of the (Ga, Al, In, B) component species are present, all possible compositions, including stoichiometric proportions as well as “off-stoichiometric” proportions (with respect to the relative mole fractions present of each of the (Ga, Al, In, B) component species that are present in the composition), can be employed within the broad scope of the invention. Accordingly, it will be appreciated that the discussion of the invention hereinafter in reference to GaN materials is applicable to the formation of various other (Ga, Al, In, B) N material species. Further, (Ga, Al, In, B) N materials within the scope of the invention may further include minor quantities of dopants and/or other impurity or inclusional materials.

Advantages and Improvements

Current conventional commercially-available (Ga, Al, In, B) N LD structures are grown on the c-plane of the wurtzite (Ga, Al, In, B) N crystal structure. Due to the lack of a robust selective etching process, manufacturers typically use timing and/or laser interferometry techniques to control ridge waveguide etch depths. Such techniques often have issues with reproducibility and accuracy, causing manufacturing problems and reducing overall device yields.

Thus, a purpose of this invention is to generate (Ga, Al, In, B) N LDs with improved manufacturability and high performance. The realization of selective etching in (Ga, Al, In, B) N LDs would allow for multiple advances in the manufacturability of (Ga, Al, In, B) N LDs. Specifically, the implementation of ESLs in (Ga, Al, In, B) N LDs may lead to significant improvements in the consistency and accuracy of etching processes. These improvements provided by the present invention, for example, improvements to the consistency and accuracy of etching processes, may lead a number of advantages for (Ga, Al, In, B) N LD manufacturers, including, but not limited to, higher overall device yields, lower threshold current densities, greater modal stability, higher kink-free output power levels, and longer device lifetimes.

The proposed devices may be used as an optical source for various commercial, industrial, or scientific applications. These (Ga, Al, In, B) N LDs can be expected to find utility in the same applications as current commercially-available (Ga, Al, In, B) N LDs. These applications include solid-state projection displays, high resolution printers, high density optical data storage systems, next generation DVD players, high efficiency solid-state lighting systems, optical sensing applications, and medical applications.

### REFERENCES

The following references are incorporated by reference herein.

1. T. Takeuchi, S. Sota, M. Katsuragawa, M. Komori, H. Takeuchi, H. Amano, and I. Akasaki, Jpn. J. Appl. Phys., 36, L382 (1997).

2. J. S. Im, H. Kollmer, J. Off, A. Sohmer, F. Scholz, and A. Hangleiter, Phys. Rev. B, 57, R9435 (1998).

3. F. Della Sala, A. Di Carlo, P. Lugli, F. Bernardini, V. Fiorentini, R. Scholz, and J. M. Jancu, Appl. Phys. Lett., 74, 2002 (1999).

4. P. Waltereit, O. Brandt, A. Trampert, H. T. Grahn, J. Menninger, M. Ramsteiner, M. Reiche, and K. H. Ploog, Nature, 406, 865 (2000).

5. A. E. Romanov, T. J. Baker, S. Nakamura, and J. S. Speck, J. Appl. Phys., 100, 023522 (2006).

6. K. C. Kim, M. C. Schmidt, H. Sato, F. Wu, N. Fellows, Z. Jia, M. Saito, S. Nakamura, S. P. DenBaars, and J. S. Speck, Appl. Phys. Lett., 91, 181120 (2007).

7. D. F. Feezell, M. C. Schmidt, R. M. Farrell, K. C. Kim, M. Saito, K. Fujito, D. A. Cohen, J. S. Speck, S. P. DenBaars, and S. Nakamura, Jpn. J. Appl. Phys., 46, L284 (2007).

8. R. M. Farrell, D. F. Feezell, M. C. Schmidt, D. A. Haeger, K. M. Kelchner, K. Iso, H. Yamada, M. Saito, K. Fujito, D. A. Cohen, J. S. Speck, S. P. DenBaars, and S. Nakamura, Jpn. J. Appl. Phys., 46, L761 (2007).

9. K. M. Kelchner, Y. D. Lin, M. T. Hardy, C. Y. Huang, P. S. Hsu, R. M. Farrell, D. A. Haeger, H. C. Kuo, F. Wu, K. Fujito, D. A. Cohen, A. Chakraborty, H. Ohta, J. S. Speck, S. Nakamura, and S. P. DenBaars, “Nonpolar AlGaN-cladding-free Blue Laser Diodes with InGaN Waveguiding,” to be published in Appl. Phys. Express.

10. J. Vatus, J. Chevrier, P. Delescluse, and J. F. Rochette, IEEE Trans. Electron. Devices, 33, 934 (1986).

11. B. Elman, W. F. Sharfin, F. D. Crawford, W. C. Rideout, J. Lacourse, and R. B. Lauer, Electron. Lett., 27, 2032 (1991).

12. Y. Han, S. Xue, W. Guo, Y. Luo, Z. Hao, and C. Sun, Jpn. J. Appl. Phys., 42, L1139 (2003).

13. W. K. Wang, Y. J. Li, C. K. Lin, Y. J. Chan, G. T. Chen, and J. I. Chyi, IEEE Electron. Device Lett., 25, 52 (2004).

14. D. Buttari, A. Chini, A. Chakraborty, L. McCarthy, H. Xing, T. Palacios, L. Shen, S. Keller, and U. K. Mishra, Int. J. High Speed Electron. Syst., 14, 756 (2004).

15. C. S. Oh, T. H. Kim, K. Y. Lim, and J. W. Yang, Semicond. Sci. Technol., 19, 172 (2004).

16. S. Salimian and C. B. Cooper III, J. Vac. Sci. Technol. B, 6, 1641 (1988).

17. R. M. Farrell, M. T. Hardy, H. Ohta, S. P. DenBaars, J. S. Speck, and S. Nakamura, “Structure for Improving the Mirror Facet Cleaving Yield of (Ga, Al, In, B) N Laser Diodes Grown on Nonpolar or Semipolar (Ga, Al, In, B) N Substrates,” Disclosure and Record of Invention Form, University of California, Santa Barbara (2009).

18. M. Hansen: Dr. Thesis, Materials Department, University of California, Santa Barbara (2001).

19. D. Buttari, A. Chini, T. Palacios, R. Coffie, L. Shen, H. Xing, S. Heikman, L. McCarthy, A. Chakraborty, S. Keller, and U. K. Mishra, Appl. Phys. Lett., 83, 4779 (2003).

20. S. Nakamura, M. Senoh, S. Nagahama, N. Iwasa, T. Yamada, T. Matsushita, H. Kiyoku, Y. Sugimoto, T. Kozaki, H. Umemoto, M. Sano, and K. Chocho, Appl. Phys. Lett., 72, 211 (1998).

21. S. Nakamura and G. Fasol, The Blue Laser Diode, (Springer, Heidelberg, 1997). This book provides an overview of c-plane (Ga, Al, In, B) N optoelectronics technology.

22. L. Coldren and S. Corzine, Diode Lasers and Photonic Integrated Circuits, (Wiley, New York, 1995). This book provides an overview of the theory and design of semiconductor lasers.

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. An optoelectronic device, comprising:
a (Ga, Al, In, B) N laser diode with one or more Al-containing etch stop layers.

2. The device of claim 1, wherein the etch stop layers are layers that are used to control an etch depth of one or more etched layers in the device.

3. The device of claim 2, wherein the etched layers comprise selectively etched layers between the etch stop layers and other layers in the device.

4. The device of claim 1, wherein the etch stop layers are bordered by layers comprised of n-type doped, p-typed doped, or undoped GaN.

5. The device of claim 1, wherein the etch stop layers are bordered by layers comprised of n-type doped, p-typed doped, or undoped alloys of (Ga, Al, In, B) N.

6. The device of claim 1, wherein the etch stop layers also function as electron blocking layers.

7. The device of claim 1, wherein the etch stop layers do not function as electron blocking layers.

8. A method of fabricating a semiconductor device, comprising:
fabricating a (Ga, Al, In, B) N laser diode with one or more Al-containing etch stop layers.

9. The method of claim 8, wherein the etch stop layers are layers that are used to control an etch depth of one or more etched layers in the device.

10. The method of claim 9, wherein the etched layers comprise selectively etched layers between the etch stop layers and other layers in the device.

11. The method of claim 8, wherein a plasma containing BCl₃ and SF₆ is used to achieve selective etching between the etch stop layers and other layers in the device.

12. The method of claim 8, wherein a plasma containing reactants other than BCl₃ and SF₆ is used to achieve selective etching between the etch stop layers and other layers in the device.

13. The method of claim 8, wherein one or more solution-based etchants are used to achieve selective etching between the etch stop layers and the other layers in the device.

14. The method of claim 8, wherein the etch stop layers are bordered by layers comprised of n-type doped, p-typed doped, or undoped GaN.

15. The method of claim 8, wherein the etch stop layers are bordered by layers comprised of n-type doped, p-typed doped, or undoped alloys of (Ga, Al, In, B) N.

16. The method of claim 8, wherein the etch stop layers also function as electron blocking layers.

17. The method of claim 8, wherein the etch stop layers do not function as electron blocking layers.

18. A device fabricated using the method of claim 8.
